(19) United States
(12) Patent Application Publication
(10) Pub. No.: US 2024/0313143 A1
(43) Pub. Date: Sep. 19, 2024

(54) MOLYBDENUM DISELENIDE (MoSe2)/InGaN MULTISPECTRAL PHOTOELECTRIC DETECTOR AND PREPARATION METHOD AND USE THEREOF

(71) Applicant: SOUTH CHINA UNIVERSITY OF TECHNOLOGY, Guangdong (CN)

(72) Inventors: Guoqiang LI, Guangzhou (CN); Deqi KONG, Guangzhou (CN); Wenliang WANG, Guangzhou (CN); Liang CHEN, Guangzhou (CN)

(73) Assignee: SOUTH CHINA UNIVERSITY OF TECHNOLOGY, Guangzhou (CN)

(21) Appl. No.: 18/276,662

(22) PCT Filed: Dec. 30, 2021
(86) PCT No.: PCT/CN2021/143373

§ 371 Date: Aug. 10, 2023

(30) Foreign Application Priority Data
Sep. 26, 2021 (CN) 202111132346.3

(51) Int. Cl. H01L 31/101; H01L 31/0224; H01L 31/0352; H01L 31/109; H01L 31/18

(52) U.S. Cl. CPC H01L 31/1013; H01L 31/022408; H01L 31/03529; H01L 31/109; H01L 31/18

(57) ABSTRACT

A molybdenum diselenide (MoSe₂)/InGaN multispectral photoelectric detector includes a substrate, a buffer layer, an InGaN layer and a MoSe₂ layer that are arranged sequentially from bottom to top. The MoSe₂ layer partially covers the InGaN layer. The photoelectric detector further includes a barrier layer and an electrode layer. The barrier layer is provided on the InGaN layer not covered by the MoSe₂ layer and on a part of the MoSe₂ layer. The electrode layer is provided on the barrier layer and covers a part of an exposed portion of the MoSe₂ layer. A preparation method of the detector is further provided. The detector detects red light and blue light at the same time. While realizing a sensitivity enhanced micro-nano structure on a surface of a detector chip, the detector improves quantum efficiency in blue and red bands, and enhances resonant absorption for the blue light and red light.

### CROSS REFERENCE TO THE RELATED APPLICATIONS

This application is the national phase entry of International Application No. PCT/CN2021/143373, filed on Dec. 30, 2021, which is based upon and claims priority to Chinese Patent Application No. 202111132346.3, filed on Sep. 26, 2021, the entire contents of which are incorporated herein by reference.

### TECHNICAL FIELD

The present disclosure relates to the field of visible light detectors, and in particular, to a molybdenum diselenide (MoSe₂)/InGaN multispectral photoelectric detector and a preparation method and use thereof.

### BACKGROUND

III-nitride photoelectric devices and power devices have received widespread attention and focused research due to the desirable optical, electrical, thermal, chemical and mechanical properties of III-nitride semiconductor materials.

As a research hotspot in third-generation semiconductor materials, the InGaN material has good physicochemical properties. With high electronic mobility, good thermostability and excellent chemical stability of the InGaN material, the band gap of the InGaN material can be continuously adjusted from 3.4 eV to 0.7 eV by adjusting the In component of the alloy. Thus, the InGaN detector can realize continuous detection in the whole visible light band. Compared with a photomultiplier tube, the InGaN detector has the advantages of small size, portability, easy integration, high breakdown field (>1 MV/cm), low working voltage, energy saving, environmental protection, and no filter system.

In spite of certain progress made in research, the InGaN detector hasn't been put into commercial use. Material quality is a matter of concern in restricting development and application of the InGaN detector. For serious lattice mismatch (>16.9%) between the InGaN detector and the Si substrate, the InGaN epitaxial layer is prone to a high density of dislocations. On the other hand, the InGaN material is phase-separated, particularly for the high content of the In component. In response to InGaN growth of the GaN material, and due to lattice mismatch between InGaN and GaN, as thickness increases, a relaxation is presented to produce defects. These defects can serve as captured carriers. Consequently, the carrier transport property is reduced, and the InGaN detector has a lower quantum efficiency to affect its response speed, and sensitivity.

### SUMMARY

An objective of the present disclosure is to provide a MoSe₂/InGaN multispectral photoelectric detector and a preparation method thereof, to solve the above-mentioned problem. The MoSe₂/InGaN multispectral photoelectric detector provided by the present disclosure has the following advantages: Through an AlN/AlGaN/GaN buffer layer, the present disclosure reduces dislocations and releases stresses, such that the defect density is reduced from 10⁸ to 10⁵, and the grown InGaN material has better quality. By growing a high-quality two-dimensional (2D) MoSe₂ material on the InGaN, a single-layer MoSe₂ structure with a thickness of 1 nm is grown. With the MoSe₂/InGaN functional layer, the detector realizes blue and red multispectral photoelectric detection. Meanwhile, the 2D MoSe₂ has desirable conductivity and light transmission. Compared with a conventional InGaN photoelectric detector, the MoSe₂/InGaN structure has higher carrier injection efficiency in the blue band to accelerate response of the InGaN blue light detector.

Another objective of the present disclosure is to provide use of the MoSe₂/InGaN multispectral photoelectric detector. The MoSe₂/InGaN multispectral photoelectric detector is used in blue and/or red multispectral photoelectric detection.

The objective of the present disclosure is achieved by the following technical solutions:
A MoSe₂/InGaN multispectral photoelectric detector includes a substrate, a buffer layer, an InGaN layer and a MoSe₂ layer that are arranged sequentially from bottom to top, where the MoSe₂ layer partially covers the InGaN layer; and
the photoelectric detector further includes a barrier layer and an electrode layer; the barrier layer is provided on the InGaN layer not covered by the MoSe₂ layer and on a part of the MoSe₂ layer; and the electrode layer is provided on the barrier layer and covers a part of an exposed portion of the MoSe₂ layer.

The InGaN layer and the MoSe₂ layer form a MoSe₂/InGaN functional layer.

That the MoSe₂ layer partially covers the InGaN layer specifically indicates that the MoSe₂ layer forms stepwise horizontal stages on the InGaN layer. The barrier layer is provided on the InGaN layer not covered by the MoSe₂ layer and on a part of the MoSe₂ layer, and specifically the barrier layer is provided on the stepwise horizontal stages on the InGaN layer and on the part of the MoSe₂ layer.

The barrier layer is an Al₂O₃ barrier layer.

The buffer layer includes an AlN layer, an AlGaN layer and a GaN layer that are arranged sequentially from bottom to top; the AlN layer is provided on the substrate; and the InGaN layer is provided on the GaN layer.

The InGaN layer has a thickness of 100 nm to 200 nm, and the MoSe₂ layer has a thickness of 1 nm to 2 nm.

The substrate is a Si substrate.

The AlN layer, the AlGaN layer and the GaN layer respectively have a thickness of 350 nm to 450 nm, a thickness of 650 nm to 700 nm, and a thickness of 4 μm to 5 μm.

The MoSe₂ layer is located at a middle of an upper surface of the InGaN layer, and specifically two ends of the MoSe₂ layer respectively form the stepwise horizontal stages on the InGaN layer.

The barrier layer is separately provided on the two stepwise horizontal stages and neighboring parts of the MoSe₂ layer. The electrode layer is separately provided on the two barrier layers and a part of the MoSe₂ layer.

The electrode layer is shaped as an interdigital electrode. The electrode layer is a metal electrode layer, and is specifically a Ti/Au metal layer. The Ti/Au metal layer includes a Ti metal layer and an Au metal layer that are arranged from bottom to top. The Ti layer is adjacent to the barrier layer. The Ti metal layer has a thickness of 20 nm to 30 nm, and the Au metal layer has a thickness of 100 nm to 110 nm.

The preparation method of the MoSe₂/InGaN multispectral photoelectric detector includes the following steps:
(1) growing the buffer layer on the substrate by metal organic chemical vapor deposition (MOCVD), and sequentially growing the InGaN layer and the MoSe₂ layer on the buffer layer by MOCVD;
(2) etching the MoSe₂ layer, such that the MoSe₂ layer forms the stepwise horizontal stages on the InGaN layer; performing photoetching (including surface spin-coating, drying, exposure, development and oxygen plasma treatment) on the stepwise horizontal stages on the InGaN layer and the MoSe₂ layer to obtain regions for evaporating the barrier layer, and preparing the Al₂O₃ barrier layer by evaporation; and
(3) performing photoetching on each of the Al₂O₃ barrier layer (performing surface spin-coating, drying, exposure, development and oxygen plasma treatment on the Al₂O₃ barrier layer) to obtain a region for evaporating a metal electrode; and evaporating the metal electrode on the Al₂O₃ barrier layer.

The AlN layer, the AlGaN layer and the GaN layer are sequentially and epitaxially grown on the substrate by MOCVD from bottom to top at a temperature of 1,100° C. to 1,200° C., a temperature of 1,100° C. to 1,200° C. and a temperature of 1,000° C. to 1,150° C. N₂ gas has a flow of 30 sccm to 40 sccm.

The MoSe₂/InGaN layer is grown on the buffer layer by MOCVD at a temperature of 600° C. to 750° C.

The photoetching is implemented under drying time of 40 s to 50 s, exposure time of 5 s to 10 s, development time of 40 s to 50 s, and oxygen plasma treatment time of 2 min to 3 min.

The Al₂O₃ barrier layer and the metal electrode layer each have an evaporation rate of 0.23 nm/min to 0.28 nm/min.

The MoSe₂/InGaN multispectral photoelectric detector is used in blue and/or red multispectral photoelectric detection.

Compared with the prior art, the present disclosure has the following beneficial effects and advantages:

(1) The present disclosure grows the AlN/AlGaN/GaN buffer layer on the substrate by an MOCVD high-temperature epitaxial method, grows the MoSe₂/InGaN functional layer on the buffer layer by an MOCVD low-temperature epitaxial method, and prepares the Al₂O₃ barrier layer and the Ti/Au electrode on the MoSe₂/InGaN functional layer from bottom to top by photoetching and evaporation, thereby achieving the MoSe₂/InGaN multispectral photoelectric detector. The preparation method provided by the present disclosure has characteristics of the simple process, time saving, high efficiency and low energy consumption, and is beneficial for scale production.

(2) The MoSe₂/InGaN multispectral photoelectric detector provided by the present disclosure realizes the blue and red multispectral photoelectric detection through the MoSe₂/InGaN functional layer. Upon that, the present disclosure optimizes the detector and the array structure to effectively accelerate a response speed.

(3) With a 2D MoSe₂ layer, the MoSe₂/InGaN structure in the blue band has a higher carrier injection efficiency. Therefore, the MoSe₂/InGaN multispectral photoelectric detector provided by the present disclosure improves the quantum efficiency in the blue band, and realizes high-sensitivity and high-bandwidth detection.

### BRIEF DESCRIPTION OF THE DRAWINGS

FIG. 1 is a schematic cross-sectional view of a MoSe₂/InGaN multispectral photoelectric detector according to the present disclosure, where, 1-substrate, 2-buffer layer, 3-InGaNlayer, 4-MoSe₂ layer, 5-Al₂O₃ barrier layer, and 6-metal electrode layer;

FIG. 2 is a schematic top view of an electrode structure of a MoSe₂/InGaN multispectral photoelectric detector according to the present disclosure; and

FIG. 3 is an I-V curve graph of a MoSe₂/InGaN multispectral photoelectric detector prepared in Embodiment 1.

### DETAILED DESCRIPTION OF THE EMBODIMENTS

The present disclosure is further described below with reference to the embodiments, but the implementations of the present disclosure are not limited thereto.

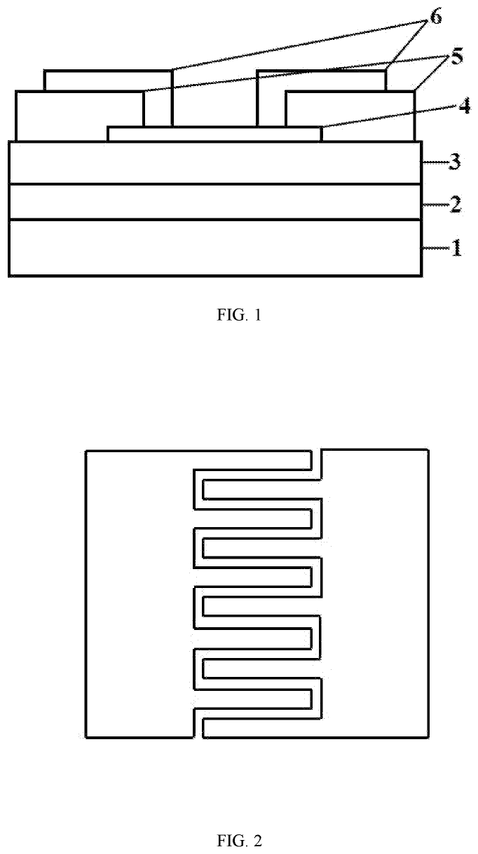

With a schematic cross-sectional view as shown in FIG. 1, a MoSe₂/InGaN multispectral photoelectric detector provided by the present disclosure includes substrate 1, buffer layer 2, InGaN layer 3, and MoSe₂ layer 4 that are arranged sequentially from bottom to top. The MoSe₂ layer forms stepwise horizontal stages on the InGaN layer.

The photoelectric detector further includes barrier layer 5 and electrode layer 6. The barrier layer 5 is provided on the stepwise horizontal stages on the InGaN layer and a part of the MoSe₂ layer. The electrode layer 6 is provided on the barrier layer 5 and covers a part of an exposed portion of the MoSe₂ layer 4.

The InGaN layer and the MoSe₂ layer form a MoSe₂/InGaN functional layer.

The barrier layer 5 is an Al₂O₃ barrier layer.

The buffer layer 2 includes an AlN layer, an AlGaN layer and a GaN layer that are arranged sequentially from bottom to top. The AlN layer is provided on the substrate 1. The InGaN layer 3 is provided on the GaN layer.

The InGaN layer has a thickness of 100 nm to 200 nm, and the MoSe₂ layer has a thickness of 1 nm to 2 nm.

The substrate is a Si substrate.

The AlN layer, the AlGaN layer and the GaN layer respectively have a thickness of 350 nm to 450 nm, a thickness of 650 nm to 700 nm, and a thickness of 4 μm to 5 μm.

Two ends of the MoSe₂ layer 4 respectively form the stepwise horizontal stages on the InGaN layer 3 (namely the MoSe₂ layer 4 is provided at a middle of the InGaN layer 3).

### Embodiment 1

The embodiment provides a MoSe₂/InGaN multispectral photoelectric detector, including a substrate, a buffer layer, an InGaN layer and a MoSe₂ layer that are arranged sequentially from bottom to top. The MoSe₂ layer forms stepwise horizontal stages on the InGaN layer. The photoelectric detector further includes a barrier layer and an electrode layer. The barrier layer is provided on the stepwise horizontal stages on the InGaN layer and a part of the MoSe₂ layer. The electrode layer is provided on the barrier layer and covers a part of an exposed portion of the MoSe₂ layer. Two ends of the MoSe₂ layer respectively form the stepwise horizontal stages on the InGaN layer (namely the MoSe₂ layer is provided at a middle of the InGaN layer). The barrier layer is provided on the two stepwise horizontal stages and neighboring parts of the MoSe₂ layer. The electrode layer is provided on the two barrier layers and a part of the MoSe₂ layer.

The substrate is a Si substrate. The InGaN layer has a thickness of 150 nm. The MoSe₂ layer has a thickness of 1.5 nm. An AlN layer, an AlGaN layer and a GaN layer respectively have a thickness of 350 nm, a thickness of 675 nm, and a thickness of 4.5 μm.

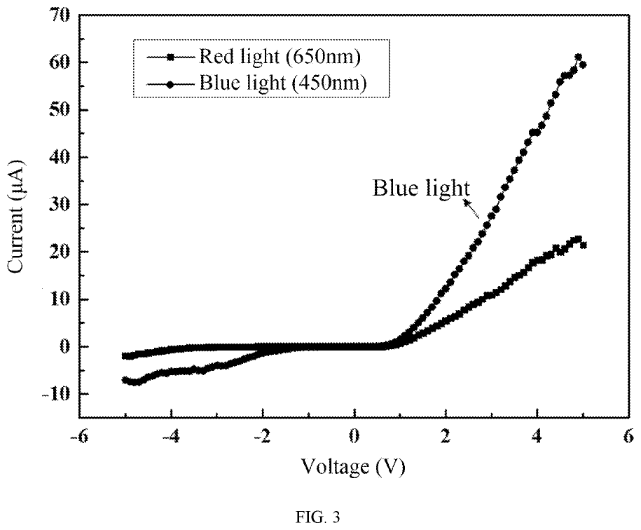

As shown in FIG. 2, the electrode is shaped as an interdigital electrode. The electrode layer is a metal electrode layer, and is specifically a Ti/Au metal layer. The Ti/Au metal layer includes a Ti metal layer and an Au metal layer that are arranged from bottom to top. The Ti layer is adjacent to the barrier layer. The Ti metal layer has a thickness of 25 nm. The Au metal layer has a thickness of 105 nm.

A preparation method of the MoSe₂/InGaN multispectral photoelectric detector includes the following steps:

(1) The buffer layer is grown on the substrate by MOCVD, and the InGaN layer and the MoSe₂ layer are sequentially grown on the buffer layer by MOCVD.

(2) The MoSe₂ layer is etched, such that the MoSe₂ layer forms the stepwise horizontal stages on the InGaN layer. Photoetching (including surface spin-coating, drying, exposure, development and oxygen plasma treatment) is performed on the stepwise horizontal stages on the InGaN layer and the MoSe₂ layer to obtain regions for evaporating the barrier layer. The Al₂O₃ barrier layer is prepared by evaporation.

(3) Photoetching is performed on each of the Al₂O₃ barrier layer (surface spin-coating, drying, exposure, development and oxygen plasma treatment are performed on the Al₂O₃ barrier layer) to obtain a region for evaporating a metal electrode. The metal electrode evaporated on the Al₂O₃ barrier layer.

The buffer layer is prepared by sequentially and epitaxially growing the AlN layer, the AlGaN layer and the GaN layer on the substrate by the MOCVD from bottom to top at a temperature of 1150° C., a temperature of 1150° C. and a temperature of 1100° C. N₂ gas has a flow of 35 sccm.

The MoSe₂/InGaN layer is grown on the buffer layer by MOCVD at a temperature of 700° C.

Steps (2) and (3) are implemented under drying time of 45 s, exposure time of 8 s, development time of 45 s, and oxygen plasma treatment time of 2.5 min.

The Al₂O₃ barrier layer and the metal electrode layer each have an evaporation rate of 0.25 nm/min.

FIG. 3 is an I-V curve graph of a MoSe₂/InGaN multispectral photoelectric detector prepared in the embodiment. As can be seen, the electrode is in Schottky contact. Under a bias voltage of 5 V, and irradiation of 650-nm red light, the photocurrent is 21 μA. Under irradiation of 450-nm blue light, the photocurrent is 50 μA. The detector has high-speed response in the blue band and the red band.

### Embodiment 2

The embodiment provides a MoSe₂/InGaN multispectral photoelectric detector, including a substrate, a buffer layer, an InGaN layer and a MoSe₂ layer that are arranged sequentially from bottom to top. The MoSe₂ layer forms stepwise horizontal stages on the InGaN layer. The photoelectric detector further includes a barrier layer and an electrode layer. The barrier layer is provided on the stepwise horizontal stages on the InGaN layer and a part of the MoSe₂ layer. The electrode layer is provided on the barrier layer and covers a part of an exposed portion of the MoSe₂ layer.

The substrate is a Si substrate. The InGaN layer has a thickness of 100 nm. The MoSe₂ layer has a thickness of 1.0 nm. An AlN layer, an AlGaN layer and a GaN layer respectively have a thickness of 350 nm, a thickness of 650 nm, and a thickness of 4.0 μm.

As shown in FIG. 2, the electrode is shaped as an interdigital electrode. The electrode layer is a metal electrode layer, and is specifically a Ti/Au metal layer. The Ti/Au metal layer includes a Ti metal layer and an Au metal layer that are arranged from bottom to top. The Ti layer is adjacent to the barrier layer. The Ti metal layer has a thickness of 20 nm. The Au metal layer has a thickness of 100 nm.

A preparation method of the MoSe₂/InGaN multispectral photoelectric detector includes the following steps:

(1) The buffer layer is grown on the substrate by MOCVD, and the InGaN layer and the MoSe₂ layer are sequentially grown on the buffer layer by MOCVD.

(2) The MoSe₂ layer is etched, such that the MoSe₂ layer forms the stepwise horizontal stages on the InGaN layer. Photoetching (including surface spin-coating, drying, exposure, development and oxygen plasma treatment) is performed on the stepwise horizontal stages on the InGaN layer and the MoSe₂ layer to obtain regions for evaporating the barrier layer. The Al₂O₃ barrier layer is prepared by evaporation.

(3) Photoetching is performed on each of the Al₂O₃ barrier layer (surface spin-coating, drying, exposure, development and oxygen plasma treatment are performed on the Al₂O₃ barrier layer) to obtain a region for evaporating a metal electrode. The metal electrode is evaporated on the Al₂O₃ barrier layer.

The buffer layer is prepared by sequentially and epitaxially growing the AlN layer, the AlGaN layer and the GaN layer on the substrate by MOCVD from bottom to top at a temperature of 1,100° C., a temperature of 1,100° C. and a temperature of 1,050° C. N₂ gas has a flow of 30 sccm.

The InGaN layer and the MoSe₂ layer are grown on the buffer layer by MOCVD at a temperature of 650° C.

Steps (2) and (3) are implemented under drying time of 40 s, exposure time of 5 s, development time of 40 s, and oxygen plasma treatment time of 2.0 min.

The Al₂O₃ barrier layer and the metal electrode layer each have an evaporation rate of 0.23 nm/min.

The MoSe₂/InGaN multispectral photoelectric detector prepared in the embodiment is tested.

The MoSe₂/InGaN multispectral photoelectric detector prepared in the embodiment has similar related performance with Embodiment 1. For related performance parameters, refer to corresponding drawings in Embodiment 1.

### Embodiment 3

The embodiment provides a MoSe₂/InGaN multispectral photoelectric detector, including a substrate, a buffer layer, an InGaN layer and a MoSe₂ layer that are arranged sequentially from bottom to top. The MoSe₂ layer forms stepwise horizontal stages on the InGaN layer. The photoelectric detector further includes a barrier layer and an electrode layer. The barrier layer is provided on the stepwise horizontal stages on the InGaN layer and a part of the MoSe₂ layer. The electrode layer is provided on the barrier layer and covers a part of an exposed portion of the MoSe₂ layer.

The substrate is a Si substrate. The InGaN layer has a thickness of 200 nm. The MoSe₂ layer has a thickness of 2.0 nm. An AlN layer, an AlGaN layer and a GaN layer respectively have a thickness of 450 nm, a thickness of 750 nm, and a thickness of 5.0 μm.

As shown in FIG. 2, the electrode is shaped as an interdigital electrode. The electrode layer is a metal electrode layer, and is specifically a Ti/Au metal layer. The Ti/Au metal layer includes a Ti metal layer and an Au metal layer that are arranged from bottom to top. The Ti layer is adjacent to the barrier layer. The Ti metal layer has a thickness of 20 nm. The Au metal layer has a thickness of 100 nm.

A preparation method of the MoSe₂/InGaN multispectral photoelectric detector includes the following steps:

(1) The buffer layer is grown on the substrate by MOCVD, and the InGaN layer and the MoSe₂ layer are sequentially grown on the buffer layer by MOCVD.

(2) The MoSe₂ layer is etched, such that the MoSe₂ layer forms the stepwise horizontal stages on the InGaN layer. Photoetching (including surface spin-coating, drying, exposure, development and oxygen plasma treatment) is performed on the stepwise horizontal stages on the InGaN layer and the MoSe₂ layer to obtain regions for evaporating the barrier layer. The Al₂O₃ barrier layer is prepared by evaporation.

(3) Photoetching is performed on each of the Al₂O₃ barrier layer (surface spin-coating, drying, exposure, development and oxygen plasma treatment are performed on the Al₂O₃ barrier layer) to obtain a region for evaporating a metal electrode. The metal electrode is evaporated on the Al₂O₃ barrier layer.

The buffer layer is prepared by sequentially and epitaxially growing the AlN layer, the AlGaN layer and the GaN layer on the substrate by MOCVD from bottom to top. The AlN layer, the AlGaN layer and the GaN layer are respectively grown at a temperature of 1,200° C., a temperature of 1,200° C. and a temperature of 1,150° C. N₂ gas has a flow of 40 sccm.

The InGaN layer and the MoSe₂ layer are grown on the buffer layer by MOCVD at a temperature of 750° C.

Steps (2) and (3) are implemented under drying time of 50 s, exposure time of 10 s, development time of 50 s, and oxygen plasma treatment time of 3.0 min.

The Al₂O₃ barrier layer and the metal electrode layer each have an evaporation rate of 0.28 nm/min.

The MoSe₂/InGaN multispectral photoelectric detector prepared in the embodiment is tested.

The MoSe₂/InGaN multispectral photoelectric detector prepared in the embodiment has similar related performance with Embodiment 1. For related performance parameters, refer to corresponding drawings in Embodiment 1.

The above embodiments are preferred implementations of the present disclosure, but the implementations of the present disclosure are not limited to these embodiments, and any other changes, modifications, substitutions, combinations and simplifications made without departing from the spirit and principle of the present disclosure shall be equivalent replacement means, and shall be included in the protection scope of the present disclosure.

What is claimed is:

1. A molybdenum diselenide (MoSe₂)/InGaN multispectral photoelectric detector, comprising a substrate, a buffer layer, an InGaN layer and a MoSe₂ layer, wherein the substrate, the buffer layer, the InGaN layer and the MoSe₂ layer are arranged sequentially from bottom to top, wherein the MoSe₂ layer partially covers the InGaN layer; and
the photoelectric detector further comprises a barrier layer and an electrode layer; the barrier layer is provided on the InGaN layer not covered by the MoSe₂ layer and on a part of the MoSe₂ layer; and the electrode layer is provided on the barrier layer and covers a part of an exposed portion of the MoSe₂ layer.

2. The MoSe₂/InGaN multispectral photoelectric detector according to claim 1, wherein
the buffer layer comprises an AlN layer, an AlGaN layer and a GaN layer, wherein the AlN layer, the AlGaN layer and the GaN layer are arranged sequentially from bottom to top; the AlN layer is provided on the substrate; and the InGaN layer is provided on the GaN layer; and
the InGaN layer has a thickness of 100 nm to 200 nm, and the MoSe₂ layer has a thickness of 1 nm to 2 nm.

3. The MoSe₂/InGaN multispectral photoelectric detector according to claim 2, wherein
the AlN layer, the AlGaN layer and the GaN layer respectively have a thickness of 350 nm to 450 nm, a thickness of 650 nm to 700 nm, and a thickness of 4 μm to 5 μm.

4. The MoSe₂/InGaN multispectral photoelectric detector according to claim 1, wherein
the substrate is a Si substrate; and
the barrier layer is an Al₂O₃ barrier layer.

5. The MoSe₂/InGaN multispectral photoelectric detector according to claim 1, wherein
that the MoSe₂ layer partially covers the InGaN layer indicates the MoSe₂ layer forms stepwise horizontal stages on the InGaN layer; and two ends of the MoSe₂ layer respectively form the stepwise horizontal stages on the InGaN layer; and
the electrode layer is shaped as an interdigital electrode; the electrode layer is a metal electrode layer, wherein the electrode layer is Ti/Au metal layer; the Ti/Au metal layer comprises a Ti metal layer and an Au metal layer, wherein the Ti metal layer and the Au metal layer are arranged from bottom to top; and the Ti layer is adjacent to the barrier layer.

6. The MoSe₂/InGaN multispectral photoelectric detector according to claim 5, wherein
the Ti metal layer has a thickness of 20 nm to 30 nm, and the Au metal layer has a thickness of 100 nm to 110 nm.

7. A preparation method of the MoSe₂/InGaN multispectral photoelectric detector according to claim 1, comprising the following steps:
(1) growing the buffer layer on the substrate by metal organic chemical vapor deposition (MOCVD), and sequentially growing the InGaN layer and the MoSe₂ layer on the buffer layer by MOCVD;
(2) etching the MoSe₂ layer, such that the MoSe₂ layer forms stepwise horizontal stages on the InGaN layer; performing photoetching on the stepwise horizontal stages on the InGaN layer and the MoSe₂ layer to obtain regions for evaporating the barrier layer; and preparing the barrier layer by evaporation; and
(3) performing photoetching on each of the barrier layer and the MoSe₂ layer not covered by the barrier layer to obtain a region for evaporating a metal electrode; and evaporating the metal electrode on the barrier layer.

8. The preparation method according to 7, wherein the buffer layer is prepared by sequentially and epitaxially growing an AlN layer, an AlGaN layer and a GaN layer on the substrate by MOCVD from bottom to top; and the AlN layer, the AlGaN layer and the GaN layer are respectively grown at a temperature of 1,100° C. to 1,200° C., a temperature of 1,100° C. to 1,200° C. and a temperature of 1,000° C. to 1,150° C.; and
the InGaN layer and the MoSe₂ layer are grown on the buffer layer by MOCVD at a temperature of 600° C. to 750° C.

9. The preparation method according to 7, wherein the barrier layer and a metal electrode layer each have an evaporation rate of 0.23 nm/min to 0.28 nm/min.

10. A method of using the MoSe₂/InGaN multispectral photoelectric detector according to claim 1, comprising: using the MoSe₂/InGaN multispectral photoelectric detector in blue and/or red multispectral photoelectric detection.

11. The preparation method according to claim 7, wherein in the MoSe₂/InGaN multispectral photoelectric detector,
the buffer layer comprises an AlN layer, an AlGaN layer and a GaN layer, wherein the AlN layer, the AlGaN layer and the GaN layer are arranged sequentially from bottom to top; the AlN layer is provided on the substrate; and the InGaN layer is provided on the GaN layer; and
the InGaN layer has a thickness of 100 nm to 200 nm, and the MoSe₂ layer has a thickness of 1 nm to 2 nm.

12. The preparation method according to claim 11, wherein in the MoSe₂/InGaN multispectral photoelectric detector,
the AlN layer, the AlGaN layer and the GaN layer respectively have a thickness of 350 nm to 450 nm, a thickness of 650 nm to 700 nm, and a thickness of 4 μm to 5 μm.

13. The preparation method according to claim 7, wherein in the MoSe₂/InGaN multispectral photoelectric detector,
the substrate is a Si substrate; and
the barrier layer is an Al₂O₃ barrier layer.

14. The preparation method according to claim 7, wherein in the MoSe₂/InGaN multispectral photoelectric detector,
that the MoSe₂ layer partially covers the InGaN layer indicates the MoSe₂ layer forms the stepwise horizontal stages on the InGaN layer; and two ends of the MoSe₂ layer respectively form the stepwise horizontal stages on the InGaN layer; and
the electrode layer is shaped as an interdigital electrode; the electrode layer is a metal electrode layer, wherein the electrode layer is a Ti/Au metal layer; the Ti/Au metal layer comprises a Ti metal layer and an Au metal layer, wherein the Ti metal layer and the Au metal layer are arranged from bottom to top; and the Ti layer is adjacent to the barrier layer.

15. The preparation method according to claim 14, wherein in the MoSe₂/InGaN multispectral photoelectric detector,
the Ti metal layer has a thickness of 20 nm to 30 nm, and the Au metal layer has a thickness of 100 nm to 110 nm.

16. The method according to claim 10, wherein in the MoSe₂/InGaN multispectral photoelectric detector,
the buffer layer comprises an AlN layer, an AlGaN layer and a GaN layer, wherein the AlN layer, the AlGaN layer and the GaN layer are arranged sequentially from bottom to top; the AlN layer is provided on the substrate; and the InGaN layer is provided on the GaN layer; and
the InGaN layer has a thickness of 100 nm to 200 nm, and the MoSe₂ layer has a thickness of 1 nm to 2 nm.

17. The method according to claim 16, wherein in the MoSe₂/InGaN multispectral photoelectric detector,
the AlN layer, the AlGaN layer and the GaN layer respectively have a thickness of 350 nm to 450 nm, a thickness of 650 nm to 700 nm, and a thickness of 4 μm to 5 μm.

18. The method according to claim 10, wherein in the MoSe₂/InGaN multispectral photoelectric detector,
the substrate is a Si substrate; and
the barrier layer is an Al₂O₃ barrier layer.

19. The method according to claim 10, wherein in the MoSe₂/InGaN multispectral photoelectric detector,
that the MoSe₂ layer partially covers the InGaN layer indicates the MoSe₂ layer forms the stepwise horizontal stages on the InGaN layer; and two ends of the MoSe₂ layer respectively form the stepwise horizontal stages on the InGaN layer; and
the electrode layer is shaped as an interdigital electrode; the electrode layer is a metal electrode layer, wherein the electrode layer is a Ti/Au metal layer; the Ti/Au metal layer comprises a Ti metal layer and an Au metal layer, wherein the Ti metal layer and the Au metal layer are arranged from bottom to top; and the Ti layer is adjacent to the barrier layer.

20. The method according to claim 19, wherein in the MoSe₂/InGaN multispectral photoelectric detector,
the Ti metal layer has a thickness of 20 nm to 30 nm, and the Au metal layer has a thickness of 100 nm to 110 nm.
